(19) United States
(12) Patent Application Publication
(10) Pub. No.: US 2026/0251976 A1
(43) Pub. Date: Aug. 27, 2026

(54) ANTIREFLECTIVE POLYMER AND HARDMASK COMPOSITION INCLUDING THE SAME

(71) Applicants: CHEMPOLE Co., LTD, Hwaseong-si (KR); Scientific Value Solutions Co. LTD, Anseong-si (KR)

(72) Inventors: Sang Jun CHOI, Yongin-si (KR); Jin Woo LEE, Anseong-si (KR); Jung Kwan BAE, Anseong-si (KR)

(73) Assignees: CHEMPOLE Co., LTD, Hwaseong-si (KR); Scientific Value Solutions Co. LTD, Anseong-si (KR)

(21) Appl. No.: 19/540,420

(22) Filed: Feb. 13, 2026

(30) Foreign Application Priority Data
Feb. 21, 2025 (KR) 10-2025-0022811

(51) Int. Cl. G03F 7/09; G03F 7/038

(52) U.S. Cl. CPC G03F 7/091; G03F 7/038

(57) ABSTRACT

The present disclosure relates to an antireflective polymer having antireflective coating properties useful for a lithography process, and a hardmask composition including the same. The antireflective polymer exhibits strong absorption in the ultraviolet (UV) wavelength range and excellent etch resistance.

### TECHNICAL FIELD

The present disclosure relates to an antireflective polymer having antireflective coating properties useful for a lithography process, and a hardmask composition including the same. More specifically, the present disclosure relates to a polymer exhibiting strong absorption in the ultraviolet (UV) wavelength range and excellent etch resistance, and a hardmask composition including the same.

### BACKGROUND

As the semiconductor industry increasingly demands finer processes, effective lithography processes have become essential to realize such ultra-fine technologies. In particular, there is a growing demand for new materials for hardmask processes, which are vital for the etching stage.

In general, a hardmask layer acts as an intermediate layer that transfers the fine pattern of a photoresist to the underlying substrate layer through a selective etching process. Therefore, the hardmask layer is required to possess properties such as chemical resistance, thermal resistance, and etch resistance to withstand multiple etching processes.

Meanwhile, a conventional hardmask layer has utilized an amorphous carbon layer (ACL) formed by chemical vapor deposition (CVD). However, this has several disadvantages, including high capital expenditure for equipment, particles generated during the process, and photo-alignment issues due to the opacity of the film, making it highly inconvenient to use.

Recently, a spin-on hardmask (SOH) technique, which forms a layer through a spin-on coating method instead of a CVD method, has been introduced. The spin-on coating method forms a hardmask composition using organic polymeric materials soluble in solvents. In this case, the most critical requirement is to form an organic polymer coating film that simultaneously possesses high etch resistance.

However, the two essential properties required for such organic hardmask layers, i.e., solubility and etch resistance, are in a trade-off relationship. Thus, there has been a need for a hardmask composition that satisfies both criteria.

Materials addressing these requirements for organic hardmask in semiconductor lithography have recently been introduced (e.g., Korean Patent Publication Nos. 10-2009-0120827, 10-2008-0107210, and WO 2013100365 A1). These materials utilize polymers with appropriate molecular weights synthesized from hydroxypyrene using conventional phenolic resin manufacturing methods.

However, as recent semiconductor lithography processes undergo further miniaturization, these organic hardmask materials have reached a stage where they cannot sufficiently perform their role as masks due to insufficient etch selectivity compared to conventional inorganic hardmask materials.

Therefore, there is an urgent need for the introduction of organic hardmask materials that are better optimized for the etching process.

### SUMMARY

To address the requirements described above, the present disclosure is intended to provide a novel polymer including an aromatic structural unit having one or more hydroxyl groups represented by Chemical Formula 1 below.

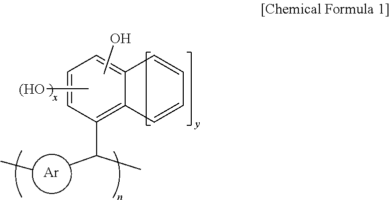

In Chemical Formula 1, an Ar group is a C6-C30 aryl group or a C6-C30 heteroaryl group, wherein the C6-C30 aryl group or C6-C30 heteroaryl group may be substituted with a hydroxyl group, a halogen group, an alkyl group, or an alkoxy group.

Furthermore, the Ar group in Chemical Formula 1 is an aromatic aryl or heteroaryl compound capable of forming condensation polymerization with a phenyl or naphthyl aldehyde compound having one or more hydroxyl groups.

In this formula, ‘x’ is in the range of 0 to 2, and ‘y’ is 0 or 1.

In addition, ‘n’ may be in the range of 5 to 100.

Additionally, the present disclosure is intended to provide a polymer for a hardmask and a composition including the same, which exhibit excellent polymer solubility, high etch selectivity, and sufficient resistance to multi-etching processes.

Furthermore, the present disclosure is intended to provide a polymer for a hardmask and a composition including the same that can be used in lithographic techniques by minimizing reflectivity between a resist and an underlayer.

According to the present disclosure, a novel polymer may consist only of an aromatic structural unit having one or more hydroxyl groups represented by Chemical Formula 1 below, wherein an Ar group in Chemical Formula 1 is a group consisting of only a single type of structural unit:

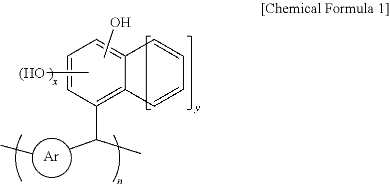

wherein the Ar group is a C6-C30 aryl group or a C6-C30 heteroaryl group, wherein the C6-C30 aryl group or C6-C30 heteroaryl group may be optionally substituted with a hydroxyl group, a halogen group, an alkyl group, an alkoxy group, or an amine group having a substituent;
the Ar group in Chemical Formula 1 is an aromatic aryl or heteroaryl compound capable of forming condensation polymerization with a phenyl or naphthyl aldehyde compound having one or more hydroxyl groups;
‘x’ is in a range of 0 to 2, and ‘y’ is 0 or 1;
‘n’ is 5 to 100; and
a weight-average molecular weight (Mw) of the polymer is in a range of 1,000 to 30,000.

According to the present disclosure, an antireflective hardmask composition may include:
(a) the aforementioned novel polymer, or a blend thereof; and
(b) an organic solvent.

The antireflective hardmask composition may further include a crosslinking agent component and an acid catalyst.

According to the present disclosure, the polymer including an aromatic structural unit formed by the condensation polymerization of a phenyl or naphthyl aldehyde having one or more hydroxyl groups with an aryl or heteroaryl compound, and the hardmask composition including the same possess a structure with a very high carbon content. This structure is highly advantageous for etch resistance and, simultaneously, exhibits excellent polymer solubility, which is very beneficial for forming uniform thin films.

Therefore, the polymer and the hardmask composition including the same according to the present disclosure have a higher etch selectivity compared to the conventional organic hardmask and possess sufficient resistance to multi-etching processes, thereby providing lithographic structures with superior pattern evaluation results.

In particular, the hardmask composition based on the polymer according to embodiments of the present disclosure possesses a refractive index and absorbance in a range useful as an antireflective coating in the Deep UV region, such as ArF (193 nm) and KrF (248 nm), during film formation. This allows for the minimization of reflectivity between the resist and the underlayer.

### DETAILED DESCRIPTION

According to the present disclosure, a novel polymer may include an aromatic structural unit having one or more hydroxyl groups represented by Chemical Formula 1 below.

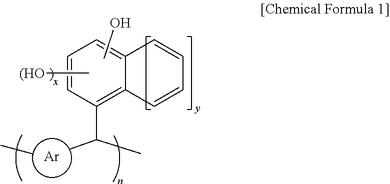

In Chemical Formula 1, an Ar group is a C6-C30 aryl group or a C6-C30 heteroaryl group, wherein the C6-C30 aryl group or C6-C30 heteroaryl group may be substituted with a hydroxyl group, a halogen group, an alkyl group, or an alkoxy group.

Furthermore, the Ar group in Chemical Formula 1 is an aromatic aryl or heteroaryl compound capable of forming condensation polymerization with a phenyl or naphthyl aldehyde compound having one or more hydroxyl groups.

In this formula, ‘x’ is in the range of 0 to 2, and ‘y’ is 0 or 1.

In addition, ‘n’ may be in the range of 5 to 100.

The Ar group may preferably have at least one of the structures represented by Chemical Formula 2 below.

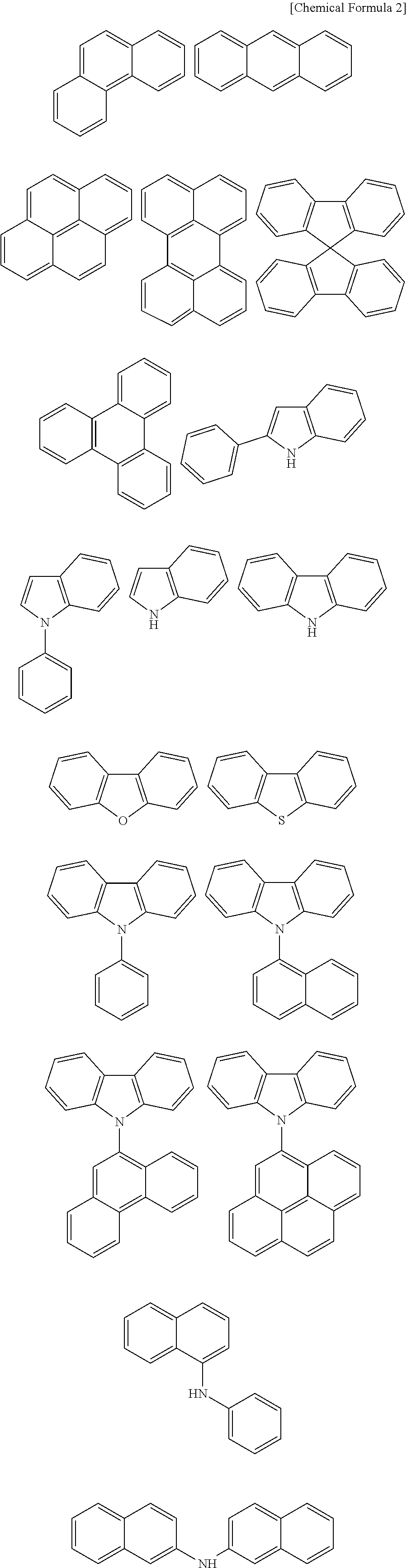

Meanwhile, the weight-average molecular weight (Mw) of the aromatic polymer ranges from 1,000 to 30,000, and preferably between 1,500 and 15,000.

The polymer including the aromatic structural unit of Chemical Formula 1 may have, for example, the forms of Chemical Formulas 2-1 to 2-26 shown below.

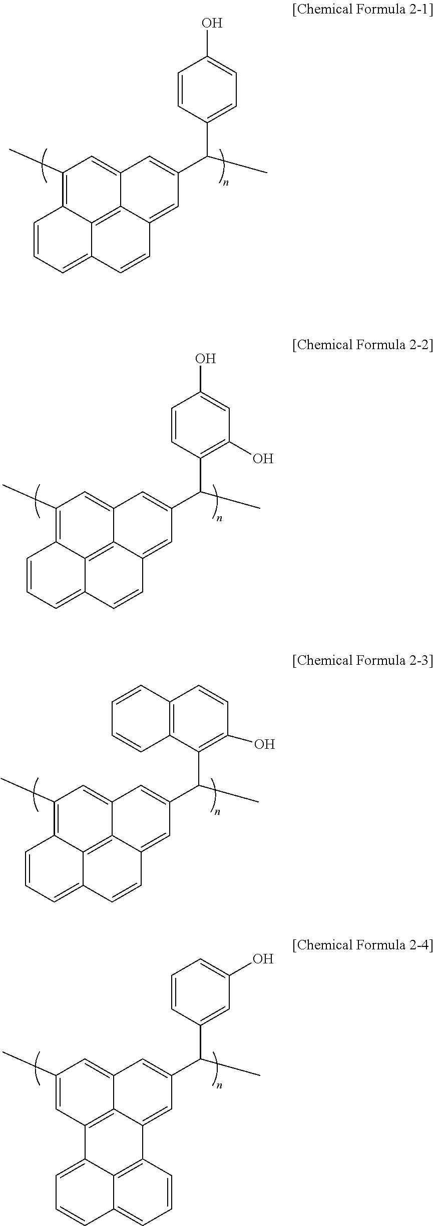

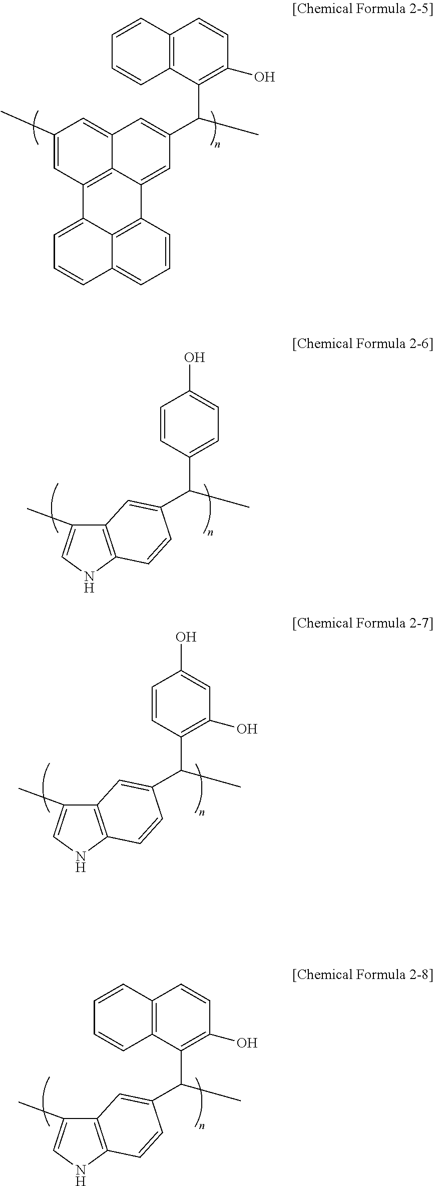

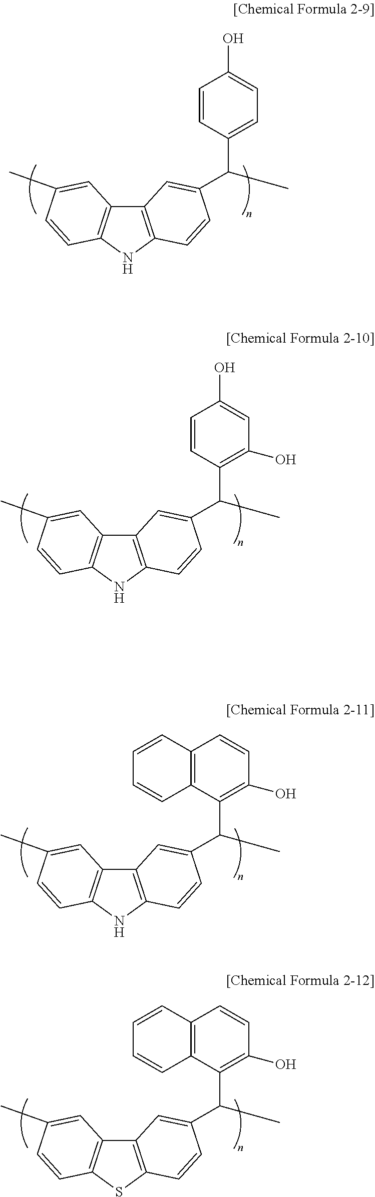

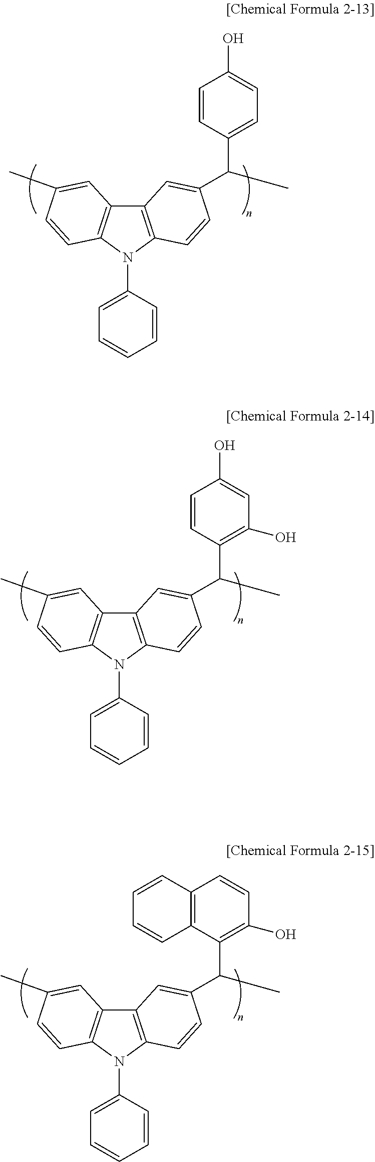

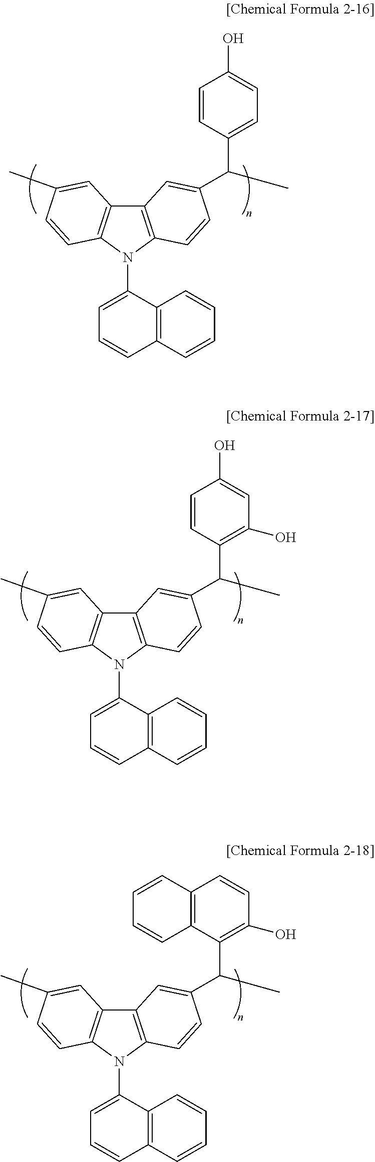

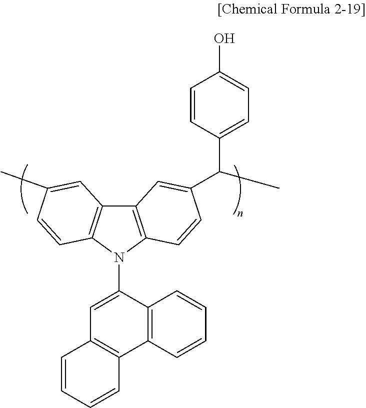

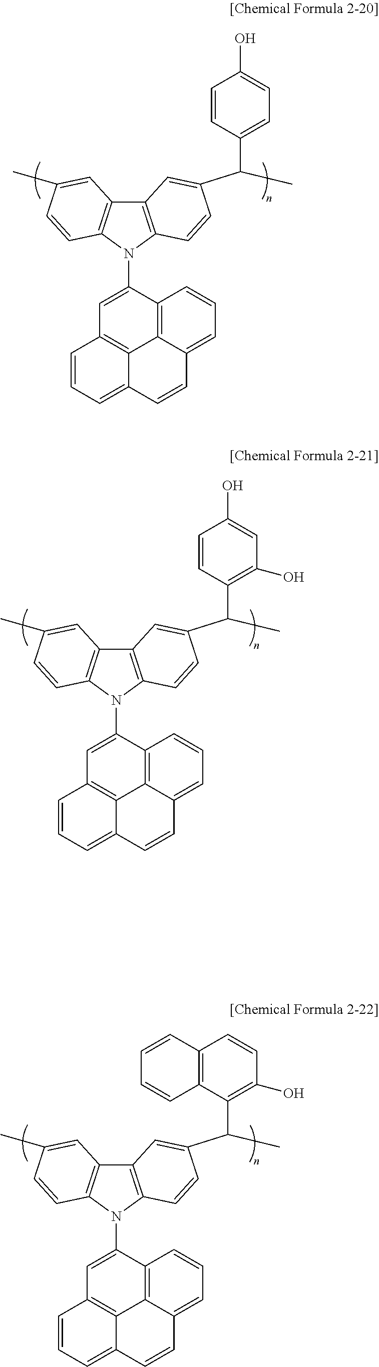

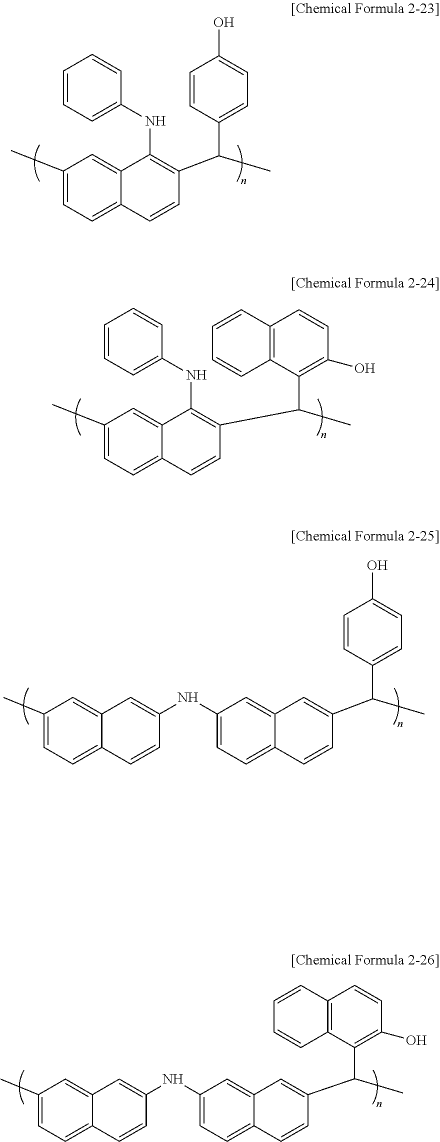

In addition, the hardmask composition of the present disclosure is an antireflective hardmask composition which includes:
(a) a polymer including an aromatic structural unit having one or more hydroxyl groups represented by Chemical Formula 1, or a blend thereof; and
(b) an organic solvent.

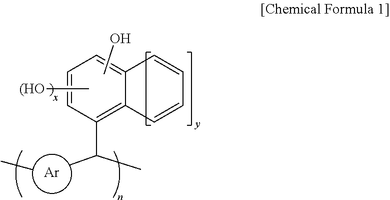

In Chemical Formula 1, an Ar group is a C6-C30 aryl group or a C6-C30 heteroaryl group, wherein the C6-C30 aryl group or C6-C30 heteroaryl group may be substituted with a hydroxyl group, a halogen group, an alkyl group, or an alkoxy group.

Furthermore, the Ar group in Chemical Formula 1 is an aromatic aryl or heteroaryl compound capable of forming condensation polymerization with a phenyl or naphthyl aldehyde compound having one or more hydroxyl groups.

In this formula, ‘x’ is in the range of 0 to 2, and ‘y’ is 0 or 1.

In addition, ‘n’ may be in the range of 5 to 100.

Meanwhile, the weight-average molecular weight (Mw) of the aromatic polymer ranges from 1,000 to 30,000, and preferably between 1,500 and 15,000.

The Ar group may preferably have at least one of the structures represented by Chemical Formula 2 below.

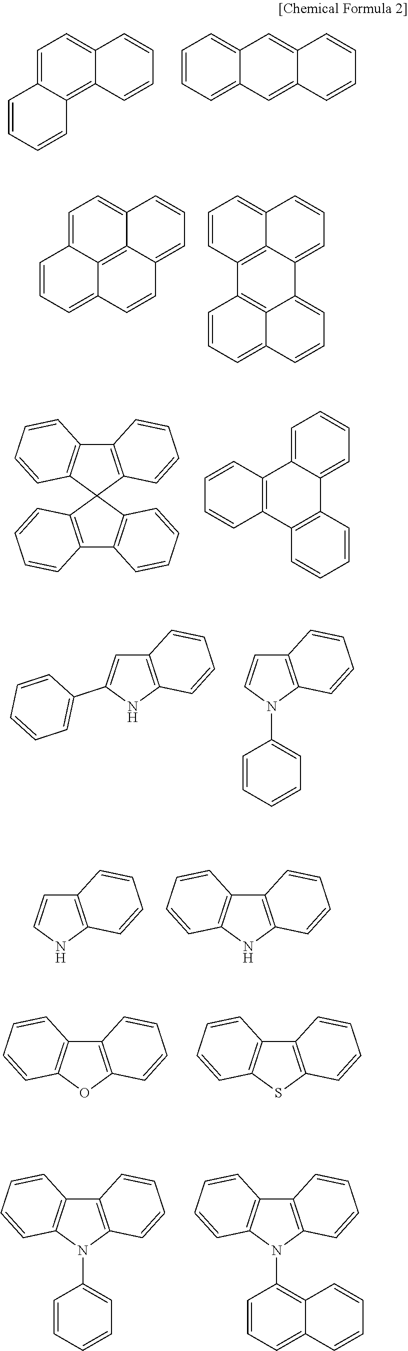

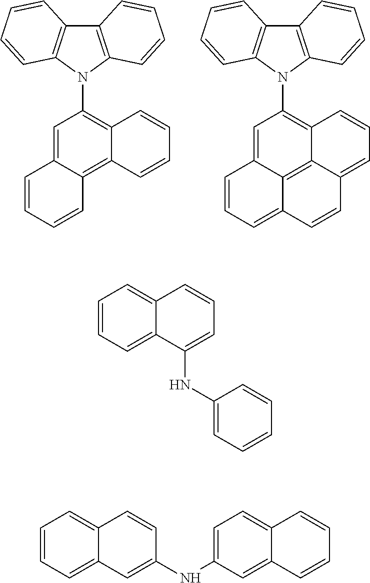

Furthermore, the polymer of (a) including the aromatic structural unit having one or more hydroxyl groups represented by Chemical Formula 1 may take the form of, for example, Chemical Formulas 2-1 to 2-26 as described above.

Moreover, the polymer of (a) including the aromatic structural unit represented by Chemical Formula 1 above may be an aromatic polymer in the form of a terpolymer, synthesized by using, in addition to the structural unit of Chemical Formula 1, other types of aldehyde compounds such as benzaldehyde, naphthylaldehyde, or fluorenone.

In addition to the polymer of (a), novolac resins or aromatic C6-C20 novolac polymers having hydroxyl groups may be further blended to improve the solubility, coatability, or curing properties of the hardmask composition.

To prepare the hardmask composition, the polymer of (a) including the aromatic structural unit having one or more hydroxyl groups represented by Chemical Formula 1, or the blend thereof, is preferably used in an amount of 1 to 30 wt % based on 100 wt % of the total composition.

If the amount of ‘the polymer or blend thereof’ in (a) is less than 1 wt % or exceeds 30 wt %, it is difficult to achieve the precise target coating thickness, as the resulting thickness may fall below or exceed the desired range.

The organic solvent of (b) is used in an amount excluding the amounts of other constituents from the 100 wt % of the total composition. The organic solvent is not particularly limited as long as it possesses sufficient solubility for the aromatic ring-containing polymer, and examples thereof include propylene glycol monomethyl ether acetate (PGMEA), cyclohexanone, ethyl lactate, and gamma-butyrolactone (GBL).

Additionally, the antireflective hardmask composition of the present disclosure may further include (c) a crosslinking agent component and (d) an acid catalyst.

The crosslinking agent component of (c) used in the hardmask composition of the present disclosure is preferably capable of crosslinking the repeating unit of the polymer through heating under the catalytic action of a generated acid. The acid catalyst of (d) is preferably a thermally activated acid catalyst.

The crosslinking agent of (c) is not particularly limited as long as it can react with the aromatic polymer in a manner that can be catalyzed by the generated acid.

Examples of the crosslinking agent include melamine-based, substituted urea-based, or polymer-based compounds thereof. Preferably, the crosslinking agent has at least two crosslink-forming substituents, and examples include compounds such as methoxymethylated glycoluril, butoxymethylated glycoluril, methoxymethylated melamine, butoxymethylated 1 melamine, methoxymethylated benzoguanamine, butoxymethylated benzoguanamine, methoxymethylated urea, butoxymethylated urea, and methoxymethylated thiourea.

Furthermore, a crosslinking agent with high heat resistance may be used, and a compound containing a crosslink-forming substituent having an aromatic ring in the molecule is preferably used.

Examples of such a compound include those represented by the following structural formulas.

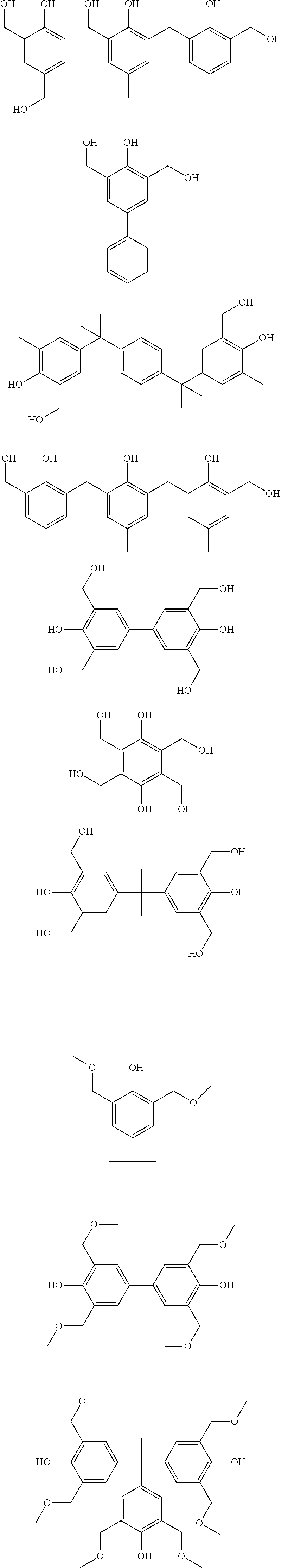

The acid catalyst of (d) used in the hardmask composition of the present disclosure may be an organic acid such as p-toluenesulfonic acid monohydrate. Additionally, a Thermal Acid Generator (TAG) based compound may be used as a catalyst to improve storage stability.

The TAG is an acid generator compound designed to release acid upon heat treatment. For example, it is preferable to use compounds such as pyridinium p-toluenesulfonate, 2,4,4,6-tetrabromocyclohexadienone, benzoin tosylate, 2-nitrobenzyl tosylate, and alkyl esters of organic sulfonic acids.

In the case where the hardmask composition further includes (c) the crosslinking agent component and (d) the acid catalyst, the hardmask composition may consist of: (a) 1 to 30 wt %, and preferably 5 to 20 wt %, of the polymer having strong absorption properties in the UV region or the blend thereof; (c) 0.1 to 5 wt %, and preferably 0.1 to 3 wt %, of the crosslinking agent component; (d) 0.001 to 0.05 wt %, and preferably 0.001 to 0.03 wt %, of the acid catalyst; and (b) the balance of the organic solvent, totaling 100 wt %. Preferably, the composition contains 75 to 98 wt % of the organic solvent.

If the amount of the polymer or blend of (a) is less than 1 wt % or exceeds 30 wt %, it is difficult to achieve the precise target coating thickness, as the thickness may fall below or exceed the desired range.

Furthermore, if the amount of the crosslinking agent component of (c) is less than 0.1 wt %, crosslinking properties may not be exhibited, and if it exceeds 5 wt %, the optical properties of the coated film may be altered due to excessive addition.

Additionally, if the amount of the acid catalyst of (d) is less than 0.001 wt %, the crosslinking properties may not be sufficiently manifested, and if it exceeds 0.05 wt %, the increased acidity caused by excessive addition may adversely affect storage stability.

Hereinafter, the present disclosure will be described in more detail through various embodiments. However, the following embodiments are provided for illustrative purposes only and are not intended to limit the scope of the present disclosure.

### <Synthesis of Polymers>

### Embodiment 1: Synthesis of Polymer

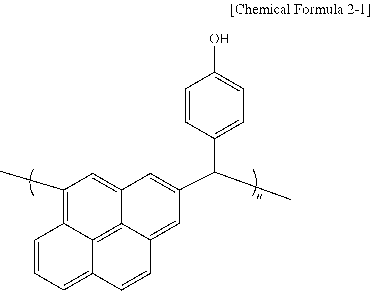

In a 250 mL round-bottom flask, pyrene (70 mmol) and 4-hydroxybenzaldehyde (90 mmol) were completely dissolved in γ-butyrolactone (GBL) (2.5 times the total weight of the monomers). Subsequently, 10 mol % of p-toluenesulfonic acid (PTSA) was added, and polymerization was carried out at a temperature of 130° C. for 20 hours.

After the completion of the polymerization, the reaction product was precipitated in an excess of a methanol/water (7:3) co-solvent and then neutralized using triethylamine. The resulting precipitate was filtered and washed twice with an excess of methanol solution. The precipitate was then collected and dried in a vacuum oven at 70° C. for 24 hours to obtain the polymer represented by Chemical Formula 2-1.

The weight-average molecular weight (Mw) of the polymer of Chemical Formula 2-1 was 2,400, and the polydispersity index (Mw/Mn) was 2.27.

### Embodiment 2: Synthesis of Polymer

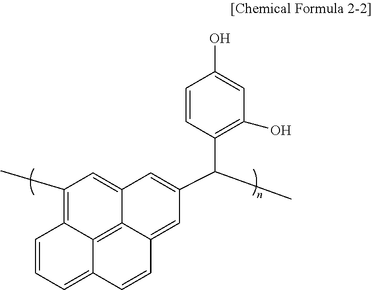

A polymer represented by Chemical Formula 2-2 was synthesized in the same manner as in Embodiment 1, except that pyrene (70 mmol) and 2,4-dihydroxybenzaldehyde (90 mmol) were used.

The weight-average molecular weight (Mw) of the polymer of Chemical Formula 2-2 was 2,300, and the polydispersity index (Mw/Mn) was 2.54.

### Embodiment 3: Synthesis of Polymer

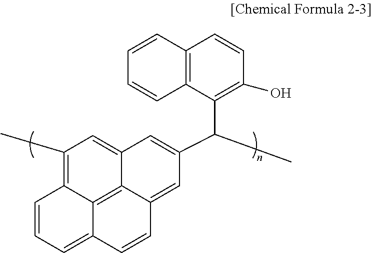

A polymer represented by Chemical Formula 2-3 was synthesized in the same manner as in Embodiment 1, except that pyrene (70 mmol) and 2-hydroxy-1-naphthaldehyde (90 mmol) were used.

The weight-average molecular weight (Mw) of the polymer of Chemical Formula 2-3 was 3,100, and the polydispersity index (Mw/Mn) was 2.59.

### Embodiment 4: Synthesis of Polymer

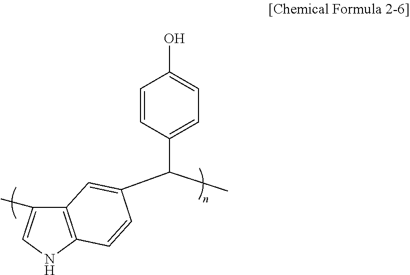

A polymer represented by Chemical Formula 2-6 was synthesized in the same manner as in Embodiment 1, except that indole (100 mmol) and 4-hydroxybenzaldehyde (110 mmol) were used.

The weight-average molecular weight (Mw) of the polymer of Chemical Formula 2-6 was 5,900, and the polydispersity index (Mw/Mn) was 2.17.

### Embodiment 5: Synthesis of Polymer

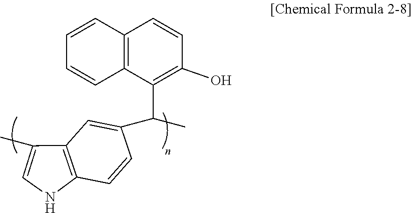

A polymer represented by Chemical Formula 2-8 was synthesized in the same manner as in Embodiment 1, except that indole (100 mmol) and 2-hydroxy-1-naphthaldehyde (110 mmol) were used.

The weight-average molecular weight (Mw) of the polymer of Chemical Formula 2-8 was 4,700, and the polydispersity index (Mw/Mn) was 2.38.

### Embodiment 6: Synthesis of Polymer

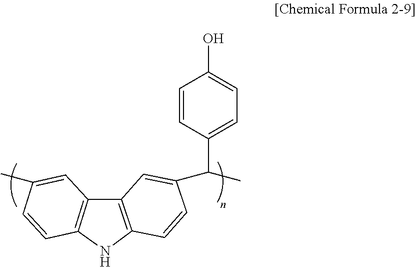

A polymer represented by Chemical Formula 2-9 was synthesized in the same manner as in Embodiment 1, except that carbazole (100 mmol) and 4-hydroxybenzaldehyde (110 mmol) were used.

The weight-average molecular weight (Mw) of the polymer of Chemical Formula 2-9 was 3,900, and the polydispersity index (Mw/Mn) was 2.57.

### Embodiment 7: Synthesis of Polymer

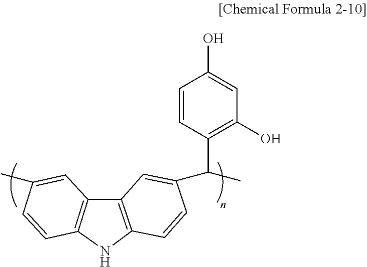

A polymer represented by Chemical Formula 2-10 was synthesized in the same manner as in Embodiment 1, except that carbazole (100 mmol) and 2,4-dihydroxybenzaldehyde (110 mmol) were used.

The weight-average molecular weight (Mw) of the polymer of Chemical Formula 2-10 was 3,300, and the polydispersity index (Mw/Mn) was 2.36.

### Embodiment 8: Synthesis of Polymer

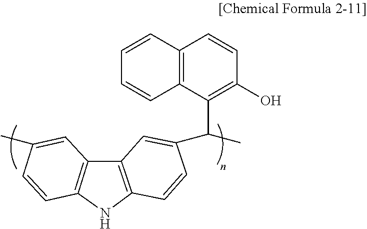

A polymer represented by Chemical Formula 2-11 was synthesized in the same manner as in Embodiment 1, except that carbazole (100 mmol) and 2-hydroxy-1-naphthaldehyde (110 mmol) were used.

The weight-average molecular weight (Mw) of the polymer of Chemical Formula 2-11 was 3,700, and the polydispersity index (Mw/Mn) was 2.28.

### Embodiment 9: Synthesis of Polymer

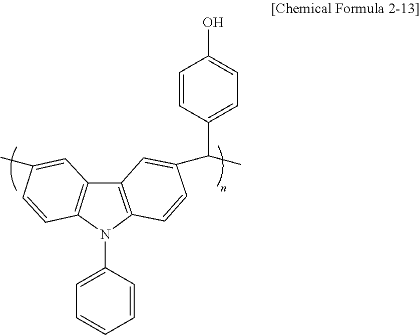

A polymer represented by Chemical Formula 2-13 was synthesized in the same manner as in Embodiment 1, except that phenylcarbazole (100 mmol) and 4-hydroxybenzaldehyde (110 mmol) were used.

The weight-average molecular weight (Mw) of the polymer of Chemical Formula 2-13 was 4,300, and the polydispersity index (Mw/Mn) was 2.18.

### Embodiment 10: Synthesis of Polymer

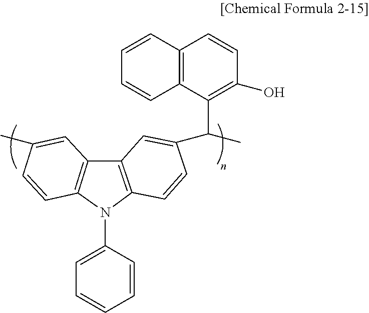

A polymer represented by Chemical Formula 2-15 was synthesized in the same manner as in Embodiment 1, except that phenylcarbazole (100 mmol) and 2-hydroxy-1-naphthaldehyde (110 mmol) were used.

The weight-average molecular weight (Mw) of the polymer of Chemical Formula 2-15 was 3,800, and the polydispersity index (Mw/Mn) was 2.18.

### Embodiment 11: Synthesis of Polymer

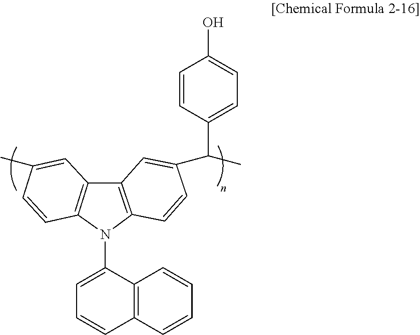

A polymer represented by Chemical Formula 2-16 was synthesized in the same manner as in Embodiment 1, except that naphthylcarbazole (100 mmol) and 4-hydroxybenzaldehyde (110 mmol) were used.

The weight-average molecular weight (Mw) of the polymer of Chemical Formula 2-16 was 3,900, and the polydispersity index (Mw/Mn) was 2.28.

### Embodiment 12: Synthesis of Polymer

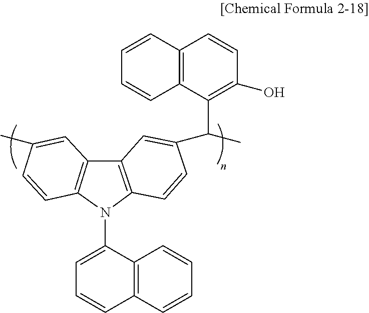

A polymer represented by Chemical Formula 2-18 was synthesized in the same manner as in Embodiment 1, except that naphthylcarbazole (100 mmol) and 2-hydroxy-1-naphthaldehyde (110 mmol) were used.

The weight-average molecular weight (Mw) of the polymer of Chemical Formula 2-18 was 3,300, and the polydispersity index (Mw/Mn) was 2.28.

### Embodiment 13: Synthesis of Polymer

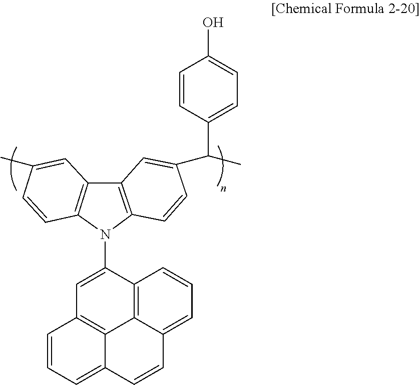

A polymer represented by Chemical Formula 2-20 was synthesized in the same manner as in Embodiment 1, except that pyrenecarbazole (60 mmol) and 4-hydroxybenzaldehyde (70 mmol) were used.

The weight-average molecular weight (Mw) of the polymer of Chemical Formula 2-20 was 3,100, and the polydispersity index (Mw/Mn) was 2.38.

### Embodiment 14: Synthesis of Polymer

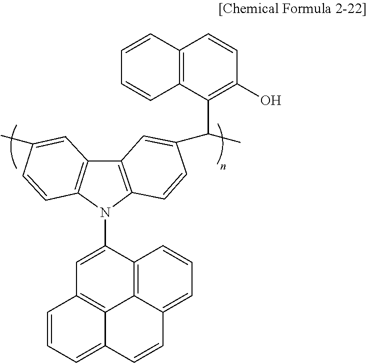

A polymer represented by Chemical Formula 2-22 was synthesized in the same manner as in Embodiment 1, except that pyrenecarbazole (60 mmol) and 2-hydroxy-1-naphthaldehyde (70 mmol) were used.

The weight-average molecular weight (Mw) of the polymer of Chemical Formula 2-22 was 2,900, and the polydispersity index (Mw/Mn) was 2.38.

### Embodiment 15: Synthesis of Polymer

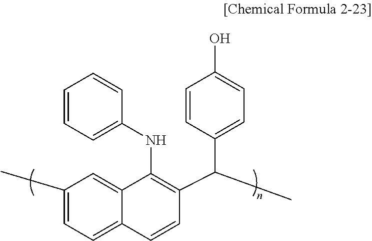

A polymer represented by Chemical Formula 2-23 was synthesized in the same manner as in Embodiment 1, except that phenyl-1-naphthylamine (100 mmol) and 4-hydroxybenzaldehyde (110 mmol) were used.

The weight-average molecular weight (Mw) of the polymer of Chemical Formula 2-23 was 3,600, and the polydispersity index (Mw/Mn) was 2.33.

### Embodiment 16: Synthesis of Polymer

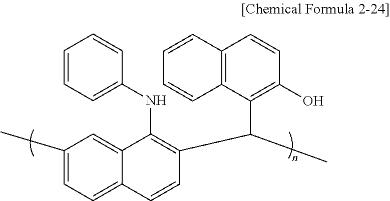

A polymer represented by Chemical Formula 2-24 was synthesized in the same manner as in Embodiment 1, except that phenyl-1-naphthylamine (100 mmol) and 2-hydroxy-1-naphthaldehyde (110 mmol) were used.

The weight-average molecular weight (Mw) of the polymer of Chemical Formula 2-24 was 3,300, and the polydispersity index (Mw/Mn) was 2.38.

### Embodiment 17: Synthesis of Polymer

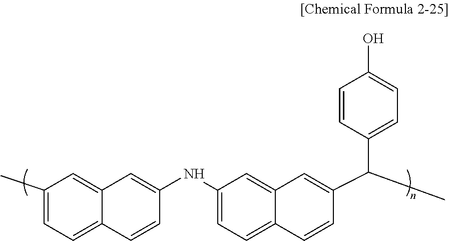

A polymer represented by Chemical Formula 2-25 was synthesized in the same manner as in Embodiment 1, except that 2,2′-dinaphthylamine (80 mmol) and 4-hydroxybenzaldehyde (90 mmol) were used.

The weight-average molecular weight (Mw) of the polymer of Chemical Formula 2-25 was 3,800, and the polydispersity index (Mw/Mn) was 2.41.

### Comparative Example: Synthesis of Phenolic Polymer

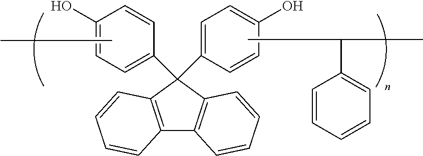

9,9-bis(hydroxyphenyl) fluorene (100 mmol) and benzaldehyde (110 mmol) were dissolved in GBL, followed by the addition of 5 mol % of p-toluenesulfonic acid.

After polymerization in the same manner as in Embodiment 1, the polymer was purified and dried in a vacuum oven to obtain a polymer with a weight-average molecular weight (Mw) of 3,300.

### <Preparation of Hardmask Compositions>

1 g of each polymer prepared in Embodiments 1, 3, 5, 8, 10, 12, 13, and 14 and the Comparative Example, along with 300 ppm of a surfactant (relative to the polymer weight), were added to a solvent mixture of 6 g of propylene glycol monomethyl ether acetate (PGMEA) and 4 g of cyclohexanone and completely dissolved. Subsequently, the solutions were filtered using a 0.2 μm membrane filter to prepare the hardmask composition sample solutions for Embodiments 1, 3, 5, 8, 10, 12, 13, and 14 and the Comparative Example, respectively.

The hardmask composition sample solutions of Embodiments 1, 3, 5, 8, 10, 12, 13, and 14 and the Comparative Example were each spin-coated onto a silicon wafer and then baked at 400° C. for 120 seconds to form films with a thickness of 3,000 Å.

The refractive index (n) and extinction coefficient (k) for the formed films were measured using an Ellipsometer (manufactured by J. A. Woollam), and the results are shown in Table 1 below.

As a result of the evaluation, it was confirmed that the films possess refractive indices and absorbances suitable for use as antireflective coatings at wavelengths of ArF (193 nm) and KrF (248 nm).

Typically, the refractive index range of materials used as semiconductor antireflective coatings is approximately 1.4 to 1.8. While the extinction coefficient is a critical factor and a higher absorbance is generally preferred, a k value of 0.3 or higher is typically sufficient for use as an antireflective coating. Therefore, it can be seen that the hardmask compositions according to the embodiments of the present disclosure are suitable for use as antireflective coatings.

TABLE 1

| | Optical Properties | | Optical Properties | |
|---|---|---|---|---|
| | (193 nm) | | (248 nm) | |
| | | Extinction | | Extinction |
| | Refractive | Coefficient | Refractive | Coefficient |
| Sample type | Index (n) | (k) | Index (n) | (k) |
| Embodiment 1 | 1.58 | 0.61 | 1.72 | 0.55 |
| Embodiment 3 | 1.57 | 0.61 | 1.74 | 0.56 |
| Embodiment 5 | 1.51 | 0.60 | 1.71 | 0.55 |
| Embodiment 8 | 1.51 | 0.63 | 1.72 | 0.54 |
| Embodiment 10 | 1.54 | 0.61 | 1.70 | 0.56 |
| Embodiment 12 | 1.57 | 0.64 | 1.72 | 0.55 |
| Embodiment 13 | 1.59 | 0.65 | 1.73 | 0.53 |
| Embodiment 14 | 1.60 | 0.64 | 1.73 | 0.57 |
| Comp. Ex. | 1.48 | 0.51 | 1.95 | 0.35 |

### <Lithographic Evaluation of Antireflective Hardmask Compositions>

Sample solutions prepared in the same manner as the hardmask compositions described above, using the polymers of Embodiments 1, 4, 6, 8, 11, and 14 and the Comparative Example, were each spin-coated onto an aluminum-deposited silicon wafer. The coated wafers were then baked at 240° C. for 60 seconds to form coating films with a thickness of 3,000 Å.

A photoresist for KrF was coated on each of the formed coating films, baked at 110° C. for 60 seconds, and exposed using an exposure system from ASML (XT: 1400, NA 0.93). Subsequently, the films were developed for 60 seconds with a 2.38 wt % aqueous solution of tetramethyl ammonium hydroxide (TMAH). Thereafter, 90 nm line-and-space patterns were observed using V-SEM, and the results are presented in Table 2 below.

Furthermore, the exposure latitude (EL) margin according to the change in exposure dose and the depth of focus (DoF) margin according to the variation in the distance from the light source were examined and recorded in Table 2.

The pattern evaluation results confirmed favorable profiles and margins. It was found that the hardmask compositions satisfy the EL margin and DoF margin requirements for lithographic pattern evaluation.

TABLE 2

| | Pattern Characteristics | | |
|---|---|---|---|
| | EL Margin | DoF Margin | |
| Sample type | (ΔmJ/energy mJ) | (μm) | Pattern Shape |
| Embodiment 1 | 0.3 | 0.3 | cubic |
| Embodiment 4 | 0.4 | 0.4 | cubic |
| Embodiment 6 | 0.4 | 0.4 | cubic |
| Embodiment 8 | 0.4 | 0.4 | cubic |
| Embodiment 11 | 0.3 | 0.4 | cubic |
| Embodiment 14 | 0.3 | 0.4 | cubic |
| Comp. Ex. | 0.2 | 0.2 | undercut |

### <Evaluation of Etch Characteristics for Antireflective Hardmask Compositions>

Hardmask compositions were prepared by completely dissolving 1 g of each polymer from Embodiments 1, 3, 5, 8, 10, 12, 13, and 14 and the Comparative Example, along with 300 ppm of a surfactant (relative to the polymer weight), in a solvent mixture of 6 g of propylene glycol monomethyl ether acetate (PGMEA) and 4 g of cyclohexanone. The compositions were then heat-treated at 400° C. for 120 seconds to form thin films. Subsequently, dry etching was performed for 60 seconds using an N₂/O₂ mixed gas (under conditions of 50 mT/300 W/10 O₂/50 N₂) and a CFx gas (under conditions of 100 mT/600 W/42 CF₄/600 Ar/15 O₂), respectively. The thickness of each thin film was measured before and after etching.

The etch rate (/s) was calculated by dividing the change in film thickness by the etching time. The results are presented in Table 3 below.

TABLE 3

| Sample | N₂/O₂ etch (/s) | CFx etch (/s) |
|---|---|---|
| Embodiment 1 | 33.5 | 21.2 |
| Embodiment 3 | 31.7 | 19.8 |
| Embodiment 5 | 34.7 | 22.0 |
| Embodiment 8 | 32.5 | 21.3 |
| Embodiment 10 | 33.6 | 22.0 |
| Embodiment 12 | 33.3 | 21.8 |
| Embodiment 13 | 32.0 | 20.1 |
| Embodiment 14 | 31.5 | 19.1 |
| Comp. Ex. | 36.1 | 35.5 |

As shown in Table 3 above, the thin films formed according to the Embodiments exhibit significantly superior etch resistance compared to the thin film formed according to the Comparative Example.

Based on these bulk etch characteristics, it is expected that the hardmask compositions prepared according to the Embodiments can serve as highly effective antireflective hardmasks for lithographic pattern formation.

Although the preferred embodiments of the present disclosure have been described in detail above, the scope of the present disclosure is not limited thereto. Various modifications and improvements made by those skilled in the art using the basic concept of the present disclosure, as defined in the following claims, also fall within the scope of the present disclosure.

What is claimed is:

1. A polymer consisting only of an aromatic structural unit having one or more hydroxyl groups represented by Chemical Formula 1 below, wherein an Ar group in Chemical Formula 1 is a group consisting of only a single type of structural unit: 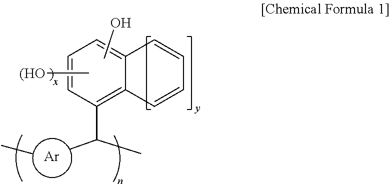
wherein the Ar group is a C6-C30 aryl group or a C6-C30 heteroaryl group, wherein the C6-C30 aryl group or C6-C30 heteroaryl group may be optionally substituted with a hydroxyl group, a halogen group, an alkyl group, an alkoxy group, or an amine group having a substituent;
the Ar group in Chemical Formula 1 is an aromatic aryl or heteroaryl compound capable of forming condensation polymerization with a phenyl or naphthyl aldehyde compound having one or more hydroxyl groups;
‘x’ is in a range of 0 to 2, and ‘y’ is 0 or 1;
‘n’ is 5 to 100; and
a weight-average molecular weight (Mw) of the polymer is in a range of 1,000 to 30,000.

2. The polymer of claim 1, wherein the Ar group is one of structures represented by Chemical Formula 2 below:

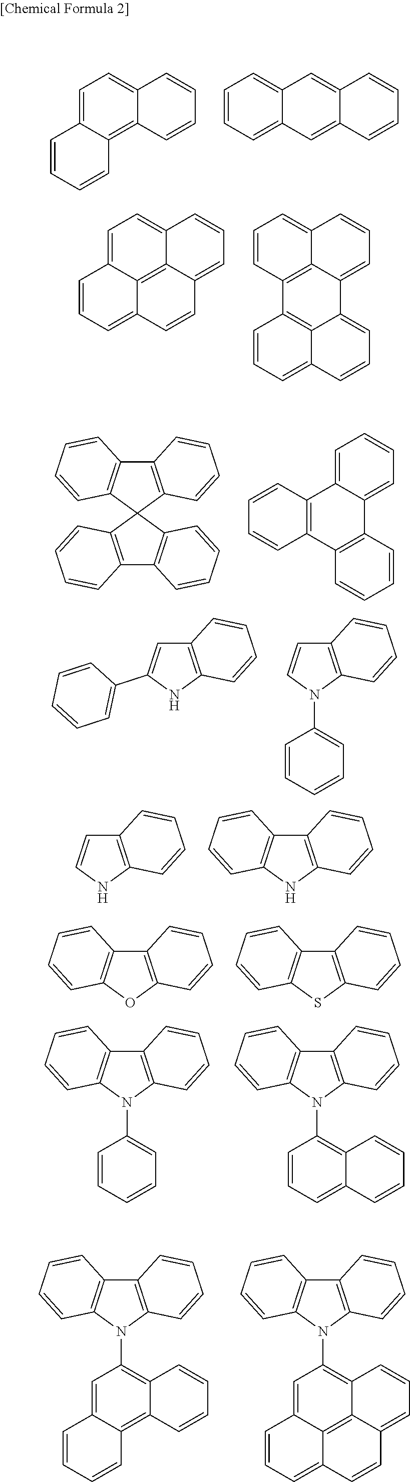

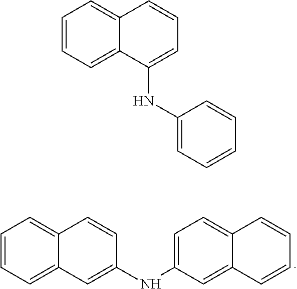 [SMILES: c1ccc(Nc2cccc3ccccc23)cc1 ; c1ccc2cc(Nc3ccc4ccccc4c3)ccc2c1]

3. The polymer of claim 1, wherein the polymer consisting only of the aromatic structural unit is one of Chemical Formulas 2-1 to 2-26 below:

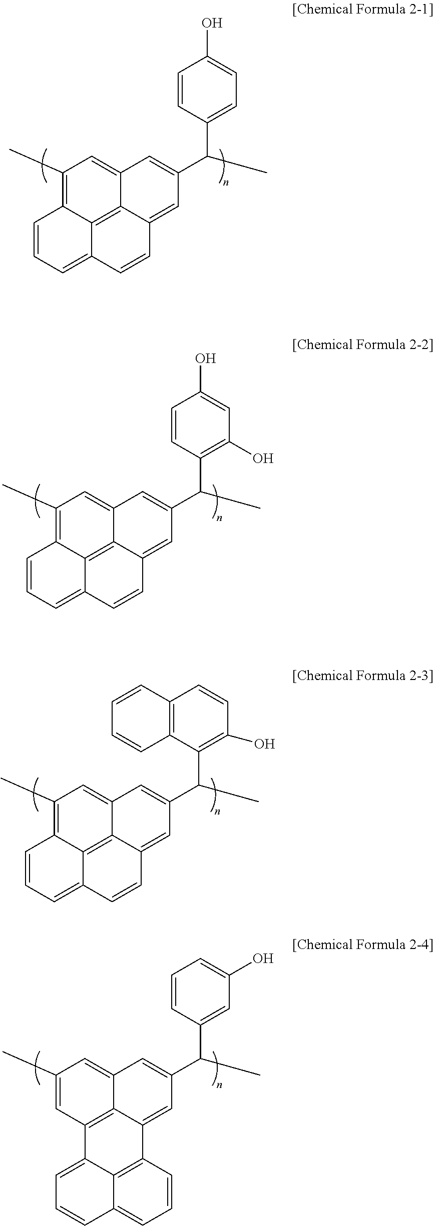

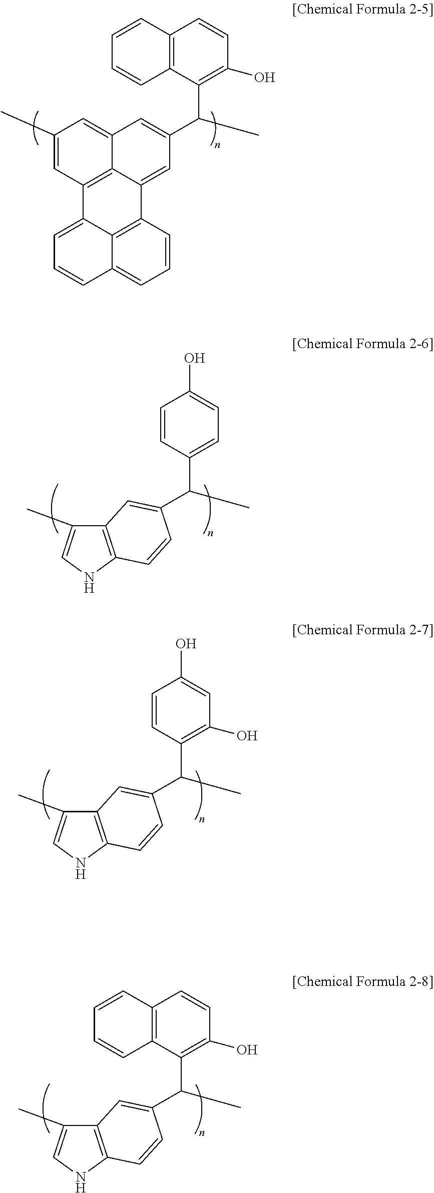

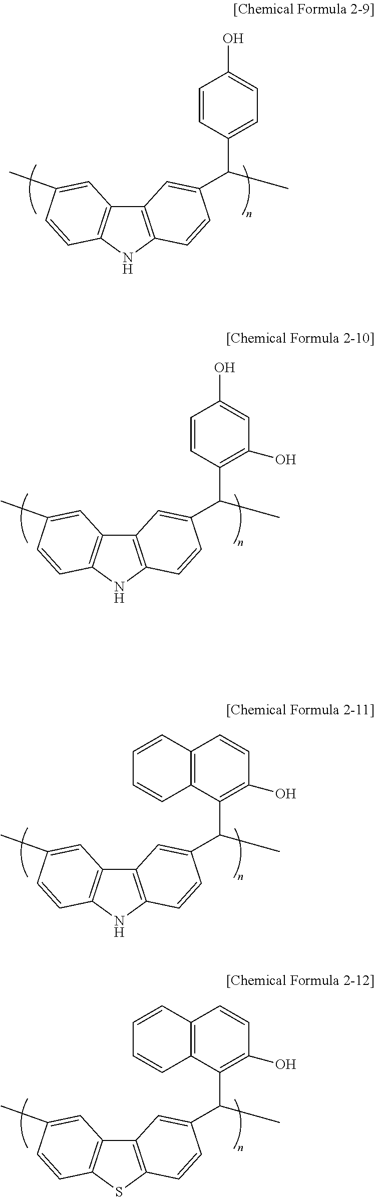

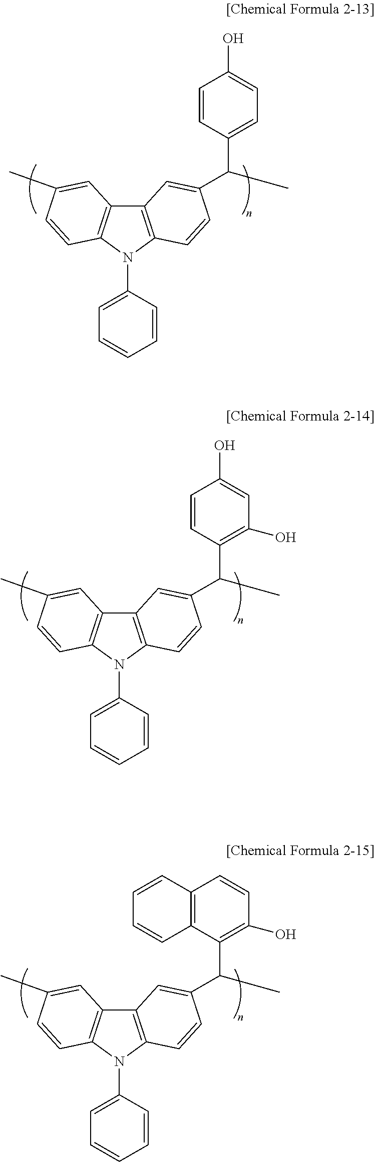

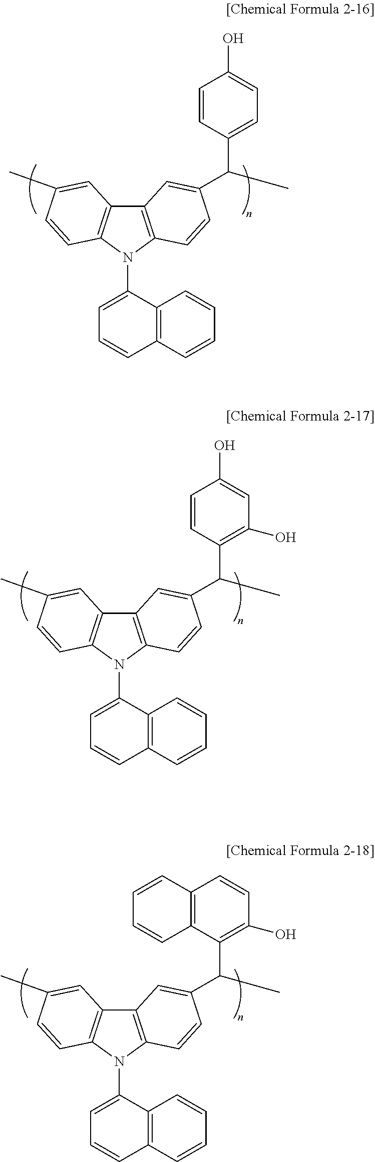

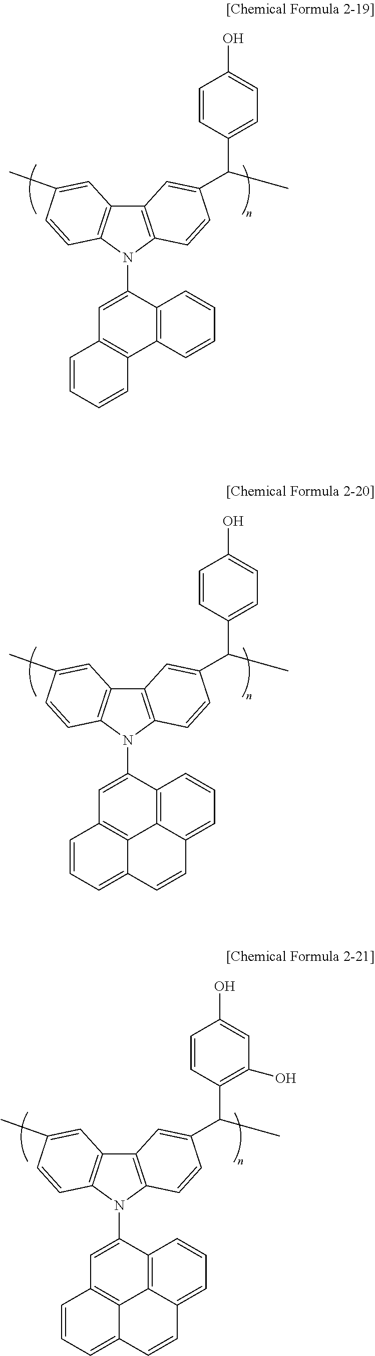

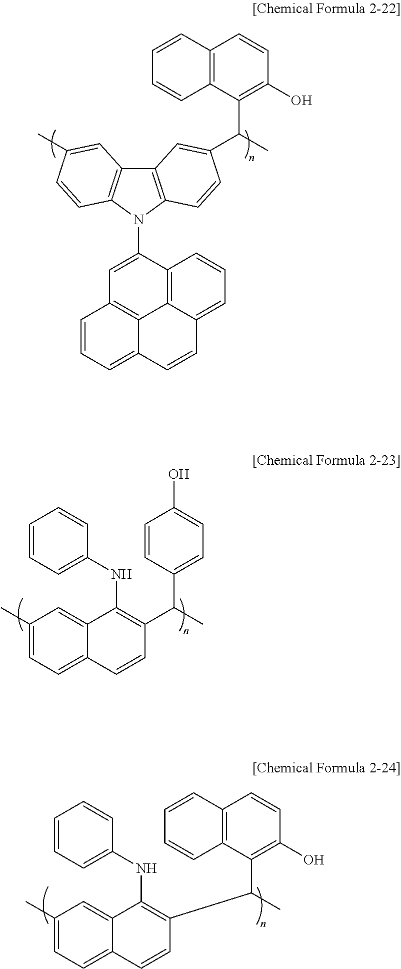

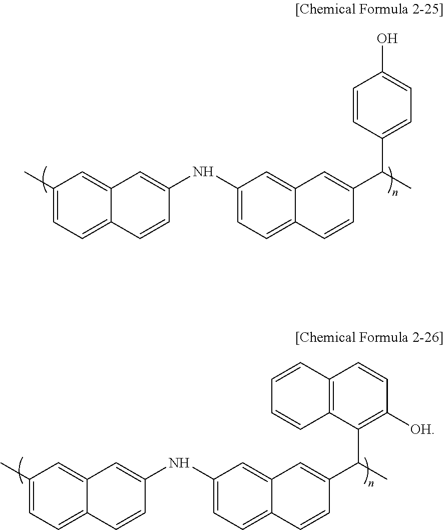

4. An antireflective hardmask composition, comprising:
(a) the polymer according to claim 1 or a blend thereof; and
(b) an organic solvent.

5. An antireflective hardmask composition, comprising:
(a) the polymer according to claim 2 or a blend thereof; and
(b) an organic solvent.

6. An antireflective hardmask composition, comprising:
(a) the polymer according to claim 3 or a blend thereof; and
(b) an organic solvent.

7. The antireflective hardmask composition of claim 4, further comprising:
a crosslinking agent component and an acid catalyst.

8. The antireflective hardmask composition of claim 5, further comprising:
a crosslinking agent component and an acid catalyst.

9. The antireflective hardmask composition of claim 6, further comprising:
a crosslinking agent component and an acid catalyst.

10. The antireflective hardmask composition of claim 7, wherein the composition consists of:
(a) 1 to 30 wt % of the polymer comprising the aromatic polymeric structural unit, or the blend thereof;
(b) 0.1 to 5 wt % of the crosslinking agent component;
(c) 0.001 to 0.05 wt % of the acid catalyst; and
(d) a balance of the organic solvent, totaling 100 wt %.

11. The antireflective hardmask composition of claim 8, wherein the composition consists of:
(a) 1 to 30 wt % of the polymer comprising the aromatic polymeric structural unit, or the blend thereof;
(b) 0.1 to 5 wt % of the crosslinking agent component;
(c) 0.001 to 0.05 wt % of the acid catalyst; and
(d) a balance of the organic solvent, totaling 100 wt %.

12. The antireflective hardmask composition of claim 9, wherein the composition consists of:
(a) 1 to 30 wt % of the polymer comprising the aromatic polymeric structural unit, or the blend thereof;
(b) 0.1 to 5 wt % of the crosslinking agent component;
(c) 0.001 to 0.05 wt % of the acid catalyst; and
(d) a balance of the organic solvent, totaling 100 wt %.

13. The antireflective hardmask composition of claim 7, wherein the crosslinking agent component is any one selected from the group consisting of: methoxymethylated glycoluril, butoxymethylated glycoluril, methoxymethylated melamine, butoxymethylated melamine, methoxymethylated benzoguanamine, butoxymethylated benzoguanamine, methoxymethylated urea, butoxymethylated urea, and methoxymethylated thiourea.

14. The antireflective hardmask composition of claim 8, wherein the crosslinking agent component is any one selected from the group consisting of: methoxymethylated glycoluril, butoxymethylated glycoluril, methoxymethylated melamine, butoxymethylated melamine, methoxymethylated benzoguanamine, butoxymethylated benzoguanamine, methoxymethylated urea, butoxymethylated urea, and methoxymethylated thiourea.

15. The antireflective hardmask composition of claim 9, wherein the crosslinking agent component is any one selected from the group consisting of: methoxymethylated glycoluril, butoxymethylated glycoluril, methoxymethylated melamine, butoxymethylated melamine, methoxymethylated benzoguanamine, butoxymethylated benzoguanamine, methoxymethylated urea, butoxymethylated urea, and methoxymethylated thiourea.

16. The antireflective hardmask composition of claim 7, wherein the acid catalyst is any one selected from the group consisting of: p-toluenesulfonic acid monohydrate, pyridinium p-toluenesulfonate, 2,4,4,6-tetrabromocyclohexadienone, benzoin tosylate, 2-nitrobenzyl tosylate, and alkyl esters of organic sulfonic acids.

17. The antireflective hardmask composition of claim 8, wherein the acid catalyst is any one selected from the group consisting of: p-toluenesulfonic acid monohydrate, pyridinium p-toluenesulfonate, 2,4,4,6-tetrabromocyclohexadienone, benzoin tosylate, 2-nitrobenzyl tosylate, and alkyl esters of organic sulfonic acids.

18. The antireflective hardmask composition of claim 9, wherein the acid catalyst is any one selected from the group consisting of: p-toluenesulfonic acid monohydrate, pyridinium p-toluenesulfonate, 2,4,4,6-tetrabromocyclohexadienone, benzoin tosylate, 2-nitrobenzyl tosylate, and alkyl esters of organic sulfonic acids.
